(19) United States
(12) Patent Application Publication
(10) Pub. No.: US 2025/0158612 A1
(43) Pub. Date: May 15, 2025

(54) INPUT BUFFERING GATE-TO-SOURCE (VGS) VOLTAGE OF A SILICON CARBIDE (SIC) FIELD-EFFECT TRANSISTOR (FET)

(71) Applicant: Microchip Technology Incorporated, Chandler, AZ (US)

(72) Inventors: David Gammie, Chandler, AZ (US); Lunal Khuon, West Chester, PA (US)

(21) Appl. No.: 18/949,712

(22) Filed: Nov. 15, 2024

Related U.S. Application Data
(60) Provisional application No. 63/599,013, filed on Nov. 15, 2023.

(51) Int. Cl. H03K 17/687

(52) U.S. Cl. CPC H03K 17/687

(57) ABSTRACT

An apparatus may include a Silicon Carbide (SiC) Field-Effect Transistor (PET) and a sense buffer circuit. The sense buffer circuit may sense a gate-to-source voltage (VGS) of the SiC PET. The sense buffer circuit may include a buffer circuit at an input of the sense buffer circuit. The buffer circuit may have a smaller input voltage range than the sense buffer circuit.

### CROSS-REFERENCE TO RELATED APPLICATION

This application claims the benefit under 35 U.S.C. § 119 (e) of U.S. Provisional Patent Application Ser. No. 63/599,013, filed Nov. 15, 2023, the disclosure of which is hereby incorporated herein in its entirety by this reference.

### TECHNICAL FIELD

One or more examples relate to input buffering a gate-to-source voltage of a silicon carbide (SiC) field-effect transistor (FET). One or more examples relate to a buffer circuit designed to sense the gate-to-source voltage (VGS) of an SiC FET, including a VGS managed by a gate driver.

### BACKGROUND

Buffer circuits are used in a variety of operational contexts, including, for example, one or more of isolation, impedance matching, enhance current-driving, voltage-level shifting, or logic-level conversion.

### BRIEF DESCRIPTION OF THE DRAWINGS

To easily identify the discussion of any particular element or act, the most significant digit or digits in a reference number refer to the figure number in which that element is first introduced. The patent or application file contains at least one drawing executed in color. Copies of this patent or patent application publication with color drawing(s) will be provided by the Office upon request and payment of the necessary fee.

FIG. 1 is a schematic diagram depicting a system including a portion of a gate driver circuit that includes a circuit for sensing a gate-to-source voltage of a Silicon Carbide (SiC) Field-Effect Transistor (FET), in accordance with one or more examples.

FIG. 2 is a schematic diagram depicting a system including a portion of a gate driver circuit that includes a circuit for sensing a gate-to-source voltage of a Silicon Carbide (SiC) Field-Effect Transistor (FET), in accordance with one or more examples

FIG. 3 is a schematic diagram depicting a system including a gate driver circuit that includes a circuit for sensing a gate-to-source voltage of a Silicon Carbide (SiC) Field-Effect Transistor (FET), in accordance with one or more examples.

FIG. 4 is a diagram depicting a graph that represents a relationship between the output of an example of a HV sense buffer circuit (e.g., HV sense buffer circuit of FIG. 1, HV sense buffer circuit of FIG. 2, HV sense buffer circuit of FIG. 3, without limitation) and an input voltage, i.e., V_{GS}.

FIG. 5 is a signal diagram depicting three signals: the input voltage, the output voltage and the difference between the input voltage and the output voltage of an example of a conventional buffer circuit. The difference illustrates the timing according to which sensed_V_{GS} follows V_{GS}.

FIG. 6 is a signal diagram depicting three signals: the input voltage, the output voltage and the difference between the input voltage and the output voltage of an example of a HV sense buffer circuit (e.g., HV sense buffer circuit of FIG. 1, HV sense buffer circuit of FIG. 2, HV sense buffer circuit of FIG. 3, without limitation).

FIG. 7 is a block diagram of circuitry that, in some examples, may be used to implement various functions, operations, acts, processes, or methods disclosed herein.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawing could be arranged and designed in a wide variety of different configurations. Thus, the following description of various embodiments is not intended to limit the scope of the present disclosure but is merely representative of various embodiments. While the various aspects of the embodiments may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Integrated Circuit (IC), an Application Specific Integrated Circuit (ASIC), a Field-Programmable Gate Array (FPGA) or other programmable logic device, discrete gate or transistor logic, discrete hardware components, or any combination thereof designed to perform the functions described herein. A general-purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer executes computing instructions (e.g., software code) related to embodiments of the present disclosure.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description the term “coupled” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

SiC FETs require carefully managed gate voltages to switch effectively between ON and OFF states. High voltage swings of VGS are necessary for this switching process; for example, a negative voltage of about −8V to −10V is applied to turn OFF the device, while a high positive voltage of about +20V to +25V is applied to turn ON the device. Gate drivers deliver these specific voltage levels to the FET's gate to establish and maintain the desired V_{GS}. The high voltage levels and wide swings between these voltage levels introduce complexities in accurately and reliably switching and sensing the gate voltage.

One or more examples relate generally to a buffer circuit designed to sense the VGS of an SiC FET using low-voltage devices. The buffer circuit enables high-voltage buffering without using high-voltage devices, instead utilizing low-voltage MOS devices in a dynamically cascoded configuration (optionally with high-voltage devices such as LDMOS). SiC MOSFETs require high positive voltages to turn ON and high negative voltages to turn OFF, which can exceed the safe operating ranges of typical low-voltage components (e.g., traditional low-voltage components known to the inventors of this disclosure). By utilizing floating inputs with diode clamping and bootstrapping techniques discussed herein, example buffer circuits can handle wide input voltage swings (e.g., −8V to +25V) without surpassing the breakdown limits of the low-voltage MOS devices.

Typical high-voltage devices like LDMOS suffer from low gain and poor matching, which limits their effectiveness in sensitive applications like VGS sensing. By utilizing low-voltage devices cascoded with LDMOS for input protection, example buffer circuits may achieve high accuracy and high speed in voltage sensing.

In typical gate driver chips for SiC FET applications, on-chip circuitry must be capable of interacting directly with high-voltage signals without damaging the circuitry or degrading performance over time. In one or more examples, buffer circuits discussed herein may provide isolation for on-chip circuitry responsible for scaling, level-shifting, and digitization from high-voltage off-chip components and/or high-voltage signals. Such signal isolation reduces risks associated with direct exposure of sensitive on-chip circuitry to high-voltage swings, enhancing the robustness and longevity of a gate driver chip without the need for high-voltage tolerant circuitry on-chip.

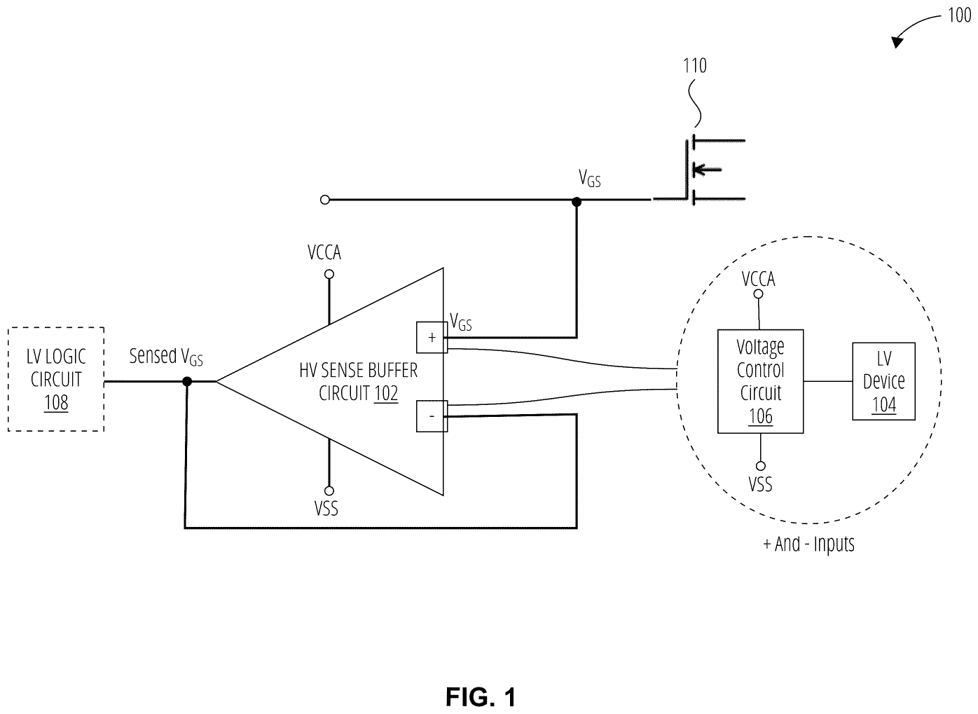

FIG. 1 is a schematic diagram depicting a system 100 that includes a portion of a gate driver circuit, in accordance with one or more examples. Specifically, system 100 includes a high voltage sense buffer circuit (buffer circuit 102) capable of sensing VGS of an SiC FET (FET 110), in accordance with one or more examples. In one or more examples, system 100 may optionally include one or more components to control the gate voltage of FET 110 at least partially responsive to signals (e.g., feedback signals, without limitation) generated by the portion of a gate driver circuit of system 100, in which case, system 100 may be considered to include a gate driver circuit for driving the gate voltage of FET 110.

While FIG. 1 depicts HV sense buffer circuit 102 utilized with an SiC FET, this disclosure is not so limited, and may be used, as non-limiting examples, in any application where an input buffer with wide input signal range is desirable.

In the example depicted by FIG. 1, system 100 includes a high voltage (HV) sense buffer circuit 102, a low voltage (LV) device 104, a voltage control circuit 106, and a low voltage (LV) logic circuit 114. Generally speaking, the high voltage sense buffer circuit 102 senses and buffers VGS of SiC FET 110, which undergoes high voltage swings for switching SiC FET 110 between ON and OFF states.

HV sense buffer circuit 102 is a unity gain buffer amplifier realized with an operational amplifier (op-amp) in a voltage follower arrangement where the output of the op-amp is directly connected to the inverting input (−), and the input signal is fed to the non-inverting input (+). This arrangement ensures the op-amp operates in a closed-loop configuration, providing an output voltage that follows the input voltage (fed to the non-inverting input). Specifically, HV sense buffer circuit 102 senses VGS of the SiC FET to the output of HV sense buffer circuit 102. Specifically, HV sense buffer circuit 102 sets the node connected to its output to sensed_V_{GS}, which follows VGS.

The non-inverting input (+) of HV sense buffer circuit 102 and/or signal path of V_{GS} to non-inverting input (+) of HV sense buffer circuit 102 includes voltage control circuit 106 and LV devices 104. The voltage control circuit 106 includes specialized high-voltage isolation features, such as clamping diodes, resistive elements, and floating input arrangements, which protect low-voltage (LV) components such as LV device 104 within the circuit from the high-voltage swings of VGS and ensure that LV devices 104 do not exceed their safe operating area.

HV sense buffer circuit 102 can handle an input voltage range beyond the range of the controlling low voltage (LV) devices (FETs) 110 that it utilizes. One or both of the positive (+) and negative (−) inputs of HV sense buffer circuit 102 may include respective instances of voltage control circuit 106 and LV device 104. The voltage control circuit 106 are low voltage, high transconductance devices that control the inputs of HV sense buffer circuit 102, i.e., the non-inverting input (+) and the inverting input (−). The positive and negative inputs of HV sense buffer circuit 102 receive voltage VCCA and VSS, which are beyond the operating range of LV devices 104. Voltage control circuit 106 controls the currents/voltage (e.g., utilizing clamps, cascades, resistors, diodes, without limitation) to LV devices 104 so the LV device 104 do not exceed their safe operating areas. In some examples, LV devices 104 may be the lowest voltage devices available for the fabrication process. By way of non-limiting example, a voltage control circuit 106 may include dynamically cascoded transistors and floating inputs with clamping diodes that track the input voltage (e.g., VGS signal, without limitation) within a specified range. The resistors and diodes control the voltage applied to gate terminals of LV FETs of buffering elements of LV devices 104, protecting them from exceeding breakdown thresholds. The result is an isolated and buffered VGS signal.

LV device 104 act as the primary buffering element that receives high-voltage signals, here VGS, indirectly through protective mechanisms offered by voltage control circuit 106, discussed later, such as clamping and resistive elements. LV device 104 ensures that the sensed_VGS output by HV sense buffer circuit 102 closely follows VGS while remaining within safe operating ranges for on-chip processing.

In one or more examples, since LV device 104 is protected by voltage control circuit 106, LV device 104 only sees a controlled portion of the high-voltage signal (e.g., a controlled version of VGS, without limitation). Thus, LV device 104 ensures that sensed_VGS matches VGS within a specific voltage range where LV device 104 operates safely. In one or more examples, voltage control circuit 106 ensures the controlled version of VGS seen by LV device 104 is within a specific voltage range which is higher than VSS and lower than VCCA, where VSS and VCCA are the low and high voltage levels between which VGS is driven. In one or more examples, the low-voltage devices (e.g., LV devices of voltage control circuit 106, without limitation) used voltage control circuit 106 to manage the high-voltage input signal (VGS) at the inputs of HV sense buffer circuit 102 may exhibit high transconductance. Stated another way, the LV components of voltage control circuit 106 may exhibit a high gain in current response relative to changes in input voltage. The high transconductance ensures the voltage control circuit 106 can replicate the VGS accurately, even as the VGS varies.

In one or more examples, one or more LV devices 104 of HV sense buffer circuit 102 may operate as a unity gain buffer that outputs a version of sensed_VGS that generally matches VGS—e.g., same magnitude of voltage swings (voltage swings between same voltage levels), but based on the controlled VGS seen by LV device 104. In other examples, one or more LV devices 104 HV sense buffer circuit 102 may optionally include circuitry to condition VGS (e.g., for use by digital circuits, without limitation) for on-chip processing, such as one or more of scaling, threshold detecting, analog-to-digital conversion, and signal processing/mixing to and so may include optional logic circuits.

LV logic circuit 108 is one or more optional logic circuits, such as analog-to-digital converters (ADC), multiplexers, comparators, threshold detectors, scaling, level shifting, without limitation. In some examples, LV logic circuit 108 may condition or further condition sensed_VGS in cases where LV devices 104 function as a unity gain buffer or do not perform all conditioning necessary for further on-chip processing of the signal. Additionally or alternatively, LV logic circuit 108 may provide on-chip processing using sensed_VGS that has been suitably conditioned.

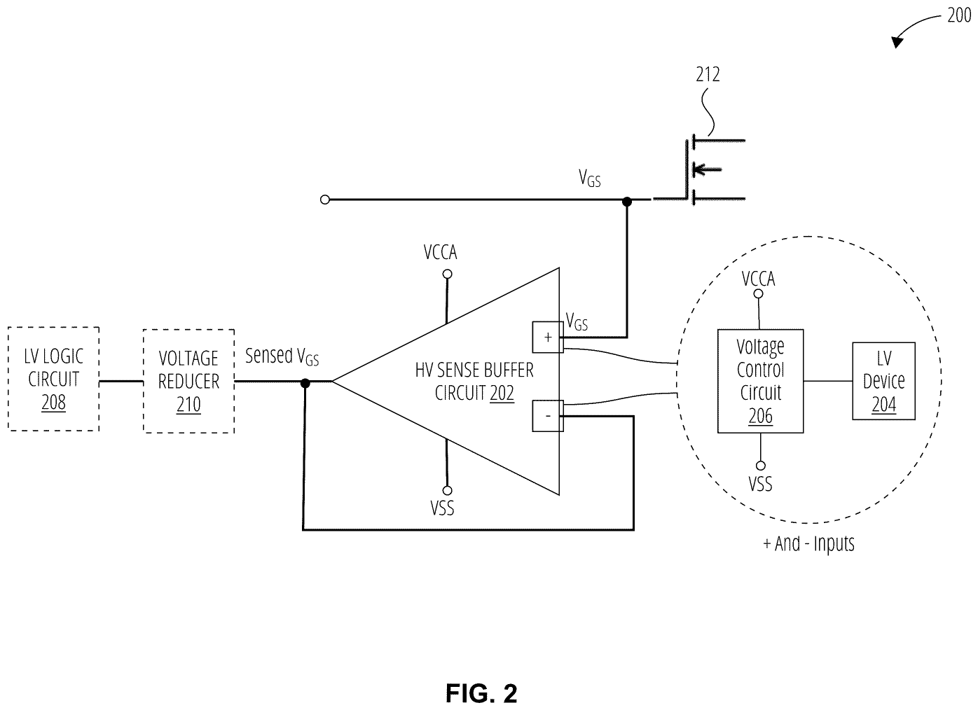

FIG. 2 is a block diagram depicting a system 200 that includes a portion of a gate driver circuit, in accordance with one or more examples. FIG. 2 is similar to FIG. 1 except it includes Voltage reducer 210 on the output of HV sense buffer circuit 202 and before LV logic circuit 208. Voltage reducer 210 reduces the voltage level of sensed_V_{GS} from a first voltage levels to a second voltage levels that are different than the first voltage levels. For example, voltage reducer 210 may reduce the amplitude of sensed_VGS so that it is within an operational range of LV logic circuit 208. The second voltage levels may be a smaller range than the first voltage levels. As a non-limiting example, the range of the first voltage levels may be VSS (low) to VCCA (high) and the second voltage range may be a fraction of VSS to a fraction of VCCA. Voltage reducer 210 may utilize any suitable voltage reducing technique to reduce sensed_VGS, for example, based on specific operating conditions. Voltage reducer 210 may be or include, as non-limiting examples, a voltage divider or voltage attenuator, without limitation.

HV sense buffer circuit 202 and Voltage reducer 210 together provide a high impedance input with level (voltage level) shifting. HV sense buffer circuit 202 conditions the signal to prepare the V_{GS} signal for level shifting. HV sense buffer circuit 202 also isolates circuits on the output of HV sense buffer circuit 102 from circuits on the input of HV sense buffer circuit 102.

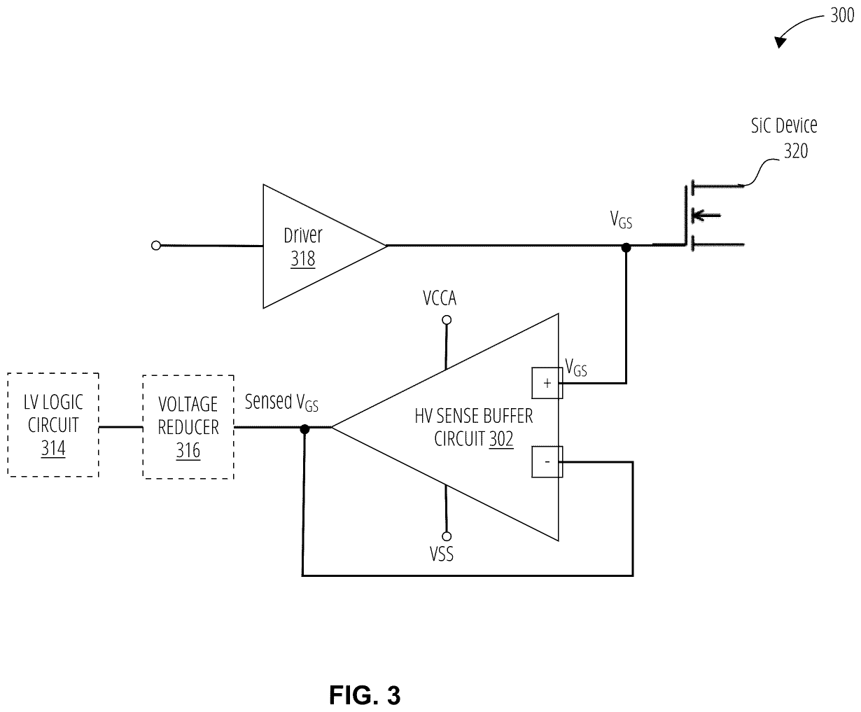

FIG. 3 is a schematic diagram depicting a system 300 that includes a gate-driver circuit, in accordance with one or more examples.

System 300 is a gate driver that includes driver 318 to drive a gate voltage VGS of an SiC device 320, here, an SiC FET. HV sense buffer circuit 302 and voltage reducer 316 provided a level shifted version of a sensed_V_{GS} to LV logic circuit 314. LV logic circuit 314 may process sensed_V_{GS} including without limitation, one or more of digitizing, scaling, comparing, calculating, without limitation. As a non-limiting example, LV logic circuit 314 may process sensed VGS for control of gate driver 300.

In one or more examples, a voltage follower circuit (not depicted) may be present between an output of driver 318 and a gate of the SiC device. Such a voltage follower may, as a non-limiting example, be provided to enhance current-driving capability.

In one or more examples, a gate driver 300 is a wide swing input buffer circuit that uses low voltage devices in a floating input condition to buffer a high voltage input swing. It is part of a unique VGS Sense block in an SiC gate driver chip implementation.

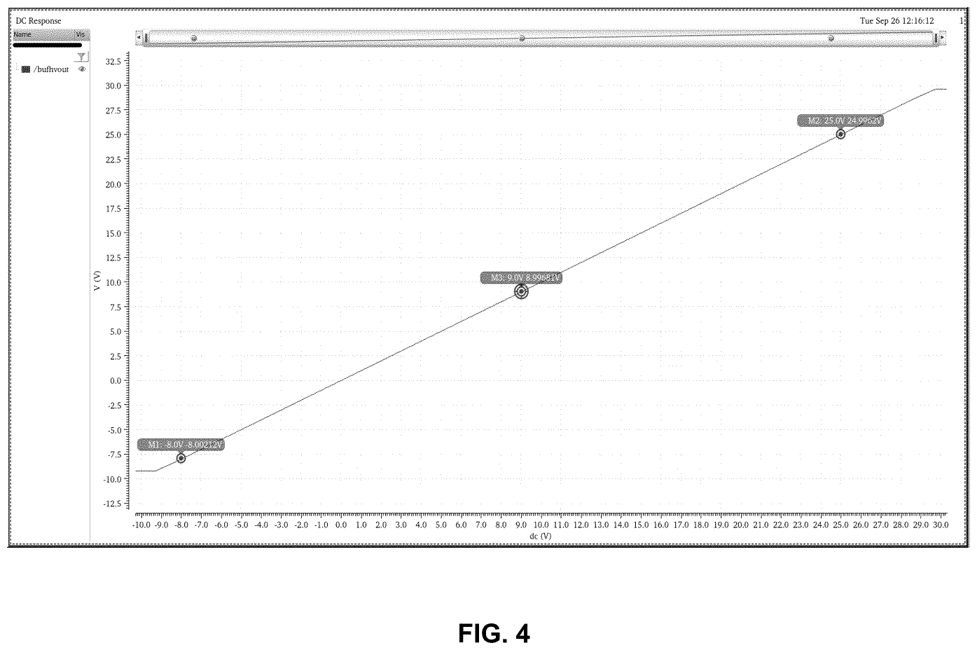

FIG. 4 is a diagram depicting a graph that represents a relationship between the output of an example of a HV sense buffer circuit (e.g., HV sense buffer circuit 102, HV sense buffer circuit 202, HV sense buffer circuit 302, without limitation) and an input voltage, i.e., V_{GS}. The output voltage ranges from −10 to 30 volts as the input voltage is swept from −10 to 30 volts during a simulation. The graph illustrates 1-to-1 gain and generally linear relationship.

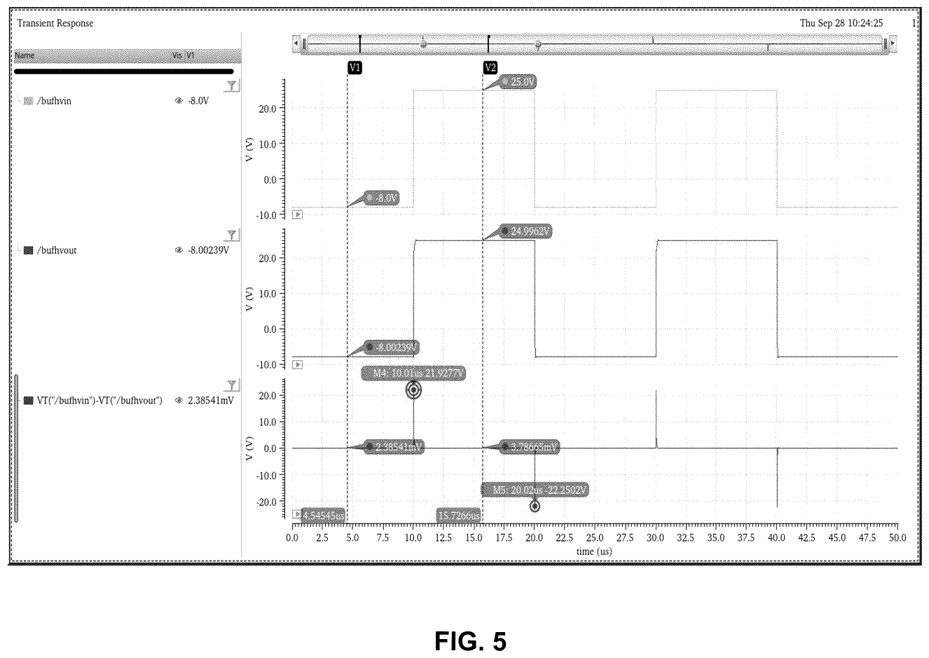

FIG. 5 is a signal diagram depicting three signals: the input voltage, the output voltage and the difference between the input voltage and the output voltage of an example of a conventional buffer circuit. The difference illustrates the timing according to which sensed_V_{GS} follows V_{GS}. The difference signal depicts a momentary difference between the input and output of up to 20 volts.

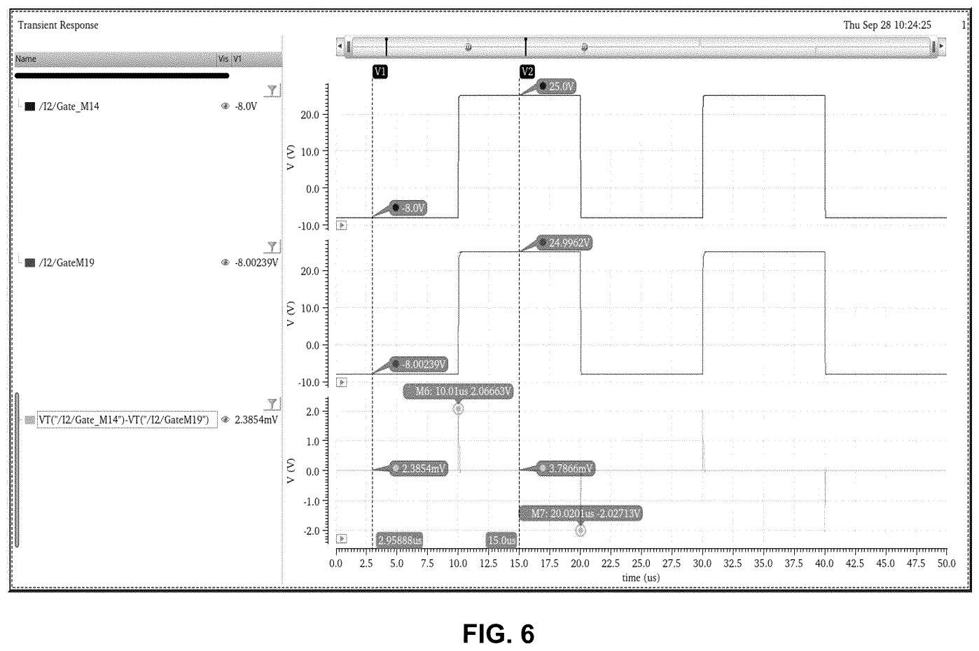

FIG. 6 is a signal diagram depicting three signals: the input voltage, the output voltage and the difference between the input voltage and the output voltage of an example of a HV sense buffer circuit (e.g., HV sense buffer circuit 102, HV sense buffer circuit 202, HV sense buffer circuit 302, without limitation). The difference illustrates the timing according to which sensed_V_{GS} follows V_{GS}. The difference signal depicts a momentary difference between the input and output of up to 2 volts.

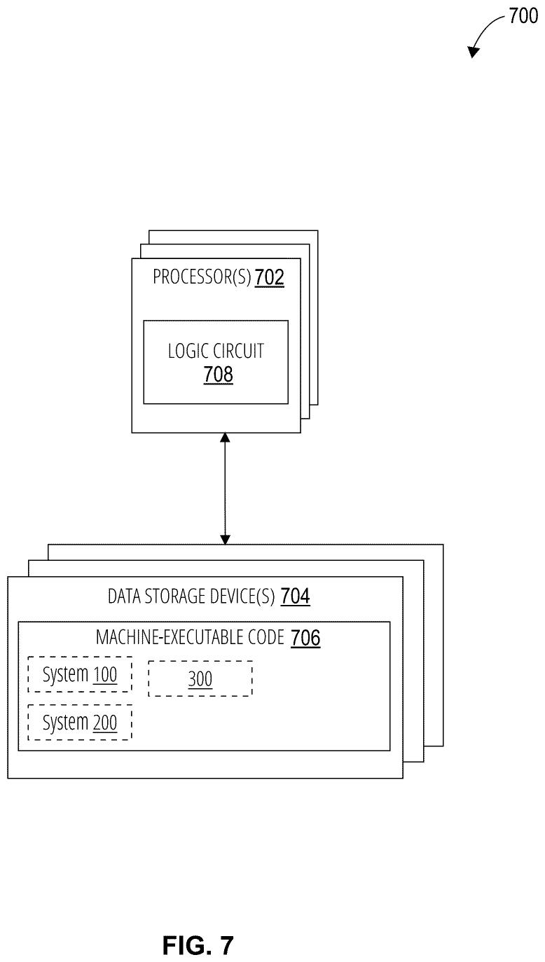

It will be appreciated by those of ordinary skill in the art that functional elements of examples disclosed herein (e.g., functions, operations, acts, processes, or methods) may be implemented in any suitable hardware, software, firmware, or combinations thereof. FIG. 7 illustrates non-limiting examples of implementations of functional elements disclosed herein. In some examples, some or all portions of the functional elements disclosed herein may be performed by hardware capable of carrying out the functional elements.

FIG. 7 is a block diagram of a circuitry 700 that, in some examples, may be used to implement various functions, operations, acts, processes, or methods disclosed herein. The circuitry 700 includes one or more processors 702 (sometimes referred to herein as “processors 702”) operably coupled to one or more data storage devices 704 (sometimes referred to herein as “storage 704”). The storage 704 includes machine-executable code 706 stored thereon and the processors 702 include logic circuit 708. The machine-executable code 706 includes information describing functional elements that may be implemented by (e.g., performed by) the logic circuit 708. The logic circuit 708 is adapted to implement (e.g., perform) the functional elements described by the machine-executable code 706. The circuitry 700, when executing the functional elements described by the machine-executable code 706, should be considered as special purpose hardware for carrying out functional elements disclosed herein. In one or more examples, the processors 702 may perform the functional elements described by the machine-executable code 706 sequentially, concurrently (e.g., on one or more different hardware platforms), or in one or more parallel process streams.

When implemented by logic circuit 708 of the processors 702, the machine-executable code 706 adapts the processors 702 to perform operations of examples disclosed herein. By way of non-limiting example, the machine-executable code 706 may adapt the processors 702 to perform some or a totality of operations of HV input buffer sensing, including for sensing of gate-to-source voltages of SiC devices discussed herein.

When implemented by logic circuit 708 of the processors 702, the machine-executable code 706 adapts the processors 702 to perform operations of examples disclosed herein. By way of non-limiting example, the machine-executable code 706 may adapt the processors 702 to perform some or a totality of features, functions, or operations disclosed herein for one or more of: 100, 200, or 300.

The processors 702 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device (PLD), discrete gate or transistor logic, discrete hardware components, other programmable device, or any combination thereof designed to perform the functions disclosed herein. A general-purpose computer including one or more processors 702, including a general-purpose processor, is considered a special-purpose computer at least while the general-purpose computer executes functional elements corresponding to the machine-executable code 706 (e.g., software code, firmware code, configuration data, hardware descriptions, without limitation) related to examples of the present disclosure. It is noted that a general-purpose processor (which may also be referred to herein as a host processor or simply a host) may be a microprocessor, but in the alternative, a general-purpose processor of processors 702 may include any conventional processor, controller, microcontroller, or state-machine. An FPGA or other PLD of the processors 702 may be configured (e.g., programmed, without limitation) with configuration data to perform functions disclosed herein, or, additionally or alternatively, may be capable of being configured or re-configured (e.g., programmable, or re-programmable, without limitation) with configuration data to perform functions disclosed herein. The processors 702 may also be implemented as a combination of computing devices, such as a combination of a DSP and a microprocessor, a plurality of microprocessors, one or more microprocessors in conjunction with a DSP core, or any other such configuration.

In one or more examples the storage 704 includes volatile data storage (e.g., random-access memory (RAM), static RAM (SRAM), without limitation), non-volatile data storage (e.g., Flash memory, a hard disc drive, a solid-state drive, erasable programmable read-only memory (EPROM), without limitation). In some examples the processors 702 and the storage 704 may be implemented into a single device (e.g., a semiconductor device product, a system on chip (SOC), without limitation). In some examples, the processors 702 and the storage 704 may be implemented into separate devices.

In one or more examples the machine-executable code 706 may include computer-readable instructions (e.g., software code, firmware code). By way of non-limiting example, the computer-readable instructions may be stored by the storage 704, accessed directly by the processors 702, and executed by the processors 702 using at least the logic circuit 708. Also, by way of non-limiting example, the computer-readable instructions may be stored on the storage 704, transferred to a memory device (not shown) for execution, and executed by the processors 702 using at least the logic circuit 708. Processors 702 or logic circuit 708 thereof be coupled to such a memory device or include such a memory device (e.g., a configuration memory cell, without limitation). Accordingly, in some examples, the logic circuit 708 includes electrically configurable logic circuit 708.

In one or more examples the machine-executable code 706 may describe hardware (e.g., circuitry) to be implemented in the logic circuit 708 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, Verilog, System Verilog or very large-scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 708 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples the machine-executable code 706 may include an HDL, an RTL, a GL description, a mask level description, other hardware description, or any combination thereof.

In examples where the machine-executable code 706 includes a hardware description (at any level of abstraction), a system (not shown, but including the storage 704) implements the hardware description described by the machine-executable code 706. By way of non-limiting example, the processors 702 may include a programmable logic device (e.g., an FPGA or a PLC, without limitation) and the logic circuit 708 may be electrically controlled (e.g., via configuration data, without limitation) to implement circuitry corresponding to the hardware description into the logic circuit 708. Also, by way of non-limiting example, the logic circuit 708 may include hard-wired logic manufactured by a manufacturing system (not shown, but including the storage 704) according to the hardware description of the machine-executable code 706.

Regardless of whether the machine-executable code 706 includes computer-readable instructions or a hardware description, the logic circuit 708 is adapted to perform the functional elements described by the machine-executable code 706 when implementing the functional elements of the machine-executable code 706. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, without limitation) of the computing system. In some examples, the different components, modules, engines, and services described in the present disclosure may be implemented as objects or processes that execute on the computing system (e.g., as separate threads). While some of the system and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additional non-limiting examples include:

Example 1: An apparatus, comprising: an SiC FET; and a sense buffer circuit to sense a gate-to-source voltage (VGS) of the SiC FET, wherein a buffer circuit at an input of the sense buffer circuit has a smaller input voltage range than the sense buffer circuit.

Example 2: The apparatus according to Example 1, wherein the sense buffer circuit includes a voltage control circuit to regulate a VGS signal of the SiC FET to ensure operation of the buffer circuit within the smaller input voltage range.

Example 3: The apparatus according to any of Examples 1 and 2, wherein the voltage control circuit includes one or more of a voltage scaler, a clamping diode, a voltage attenuator, a floating input, or a signal filter, or respectively to regulate the VGS signal.

Example 4: The apparatus according to any of Examples 1 through 3, wherein the buffer circuit to generate a buffered input voltage signal responsive to processing a regulated VGS signal generated by the voltage control circuit.

Example 5: The apparatus according to any of Examples 1 through 4, comprising: a voltage reducer to produce an output signal proportional to a buffered VGS signal and with a scaled amplitude suitable for digital processing within a logic circuit.

Example 6: The apparatus according to any of Examples 1 through 5, comprising: a logic circuit to receive a sensed VGS signal of the SiC FET from the sense buffer circuit, the sensed VGS signal within the operational range of the logic circuit.

Example 7: The apparatus according to any of Examples 1 through 6, comprising: a driver to provide voltage or current to a gate of the SiC FET suitable to switch the SiC FET between ON and OFF states.

Example 8: The apparatus according to any of Examples 1 through 7, wherein the driver to provide the voltage or current at least partially based on a sensed VGS signal of the SiC FET provided by the sense buffer circuit.

Example 9: The apparatus according to any of Examples 1 through 8, wherein the sense buffer circuit further comprises timing control circuitry to synchronize the sampling and buffering of the VGS signal, enabling real-time monitoring of the SiC FET's gate-to-source voltage.

Example 10: The apparatus according to any of Examples 1 through 9, wherein the sense buffer circuit includes signal conditioning circuitry to modify a VGS signal of the SiC FET.

Example 11: The apparatus according to any of Examples 1 through 10, wherein the signal conditioning circuitry includes one or more of an analog-to-digital converter, a multiplexer, a comparator, a threshold detector, a signal scaler, or a signal level shifter.

Example 12: The apparatus according to any of Examples 1 through 11, wherein one or more of the inputs of the sense buffer circuit include high-transconductance low-voltage circuits, configured to accurately track changes in the gate-to-source voltage of the SiC FET.

Example 13: The apparatus according to any of Examples 1 through 12, wherein the sense buffer circuit includes cascoded low-voltage devices to manage high-voltage swings of the VGS signal while maintaining safe operating conditions for the low-voltage devices.

Example 14: An apparatus, comprising: a Silicon Carbide (SiC) Field Effect Transistor (FET); a voltage control circuit to control a gate-to-source voltage (VGS) of the SiC FET; a sense buffer circuit to sense a VGS signal of the SiC FET, the sense buffer circuit comprising: one or more low-voltage (LV) devices to produce a buffered version of the VGS signal, the LV devices operating within a smaller input voltage range than the overall sense buffer circuit; a voltage control circuit to regulate the VGS signal to ensure operation of the LV devices within their input voltage range, wherein the voltage control circuit includes one or more of a voltage scaler, a clamping diode, a voltage attenuator, a floating input, or a signal filter; isolation circuitry to electrically isolate the high-voltage VGS input signal from the buffered VGS signal, the isolation circuitry including one or more of cascoded transistors, resistive voltage dividers, clamping diodes, or capacitive coupling; a voltage reducer to receive the buffered VGS signal from the sense buffer circuit and generate a sensed VGS signal with a reduced amplitude; a logic circuit to receive the sensed VGS signal, wherein the sensed VGS signal is within an operational voltage range compatible with the logic circuit; and a driver circuit to provide voltage or current to a gate of the SiC FET to switch the SiC FET between ON and OFF states, wherein the driver circuit operates based at least in part on the sensed VGS signal generated by the sense buffer circuit.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. An apparatus, comprising:
an SiC FET; and
a sense buffer circuit to sense a gate-to-source voltage (VGS) of the SiC FET,
wherein a buffer circuit at an input of the sense buffer circuit has a smaller input voltage range than the sense buffer circuit.

2. The apparatus of claim 1, wherein the sense buffer circuit includes a voltage control circuit to regulate a VGS signal of the SiC FET to ensure operation of the buffer circuit within the smaller input voltage range.

3. The apparatus of claim 2, wherein the voltage control circuit includes one or more of a voltage scaler, a clamping diode, a voltage attenuator, a floating input, or a signal filter, or respectively to regulate the VGS signal.

4. The apparatus of claim 2, wherein the buffer circuit to generate a buffered input voltage signal responsive to processing a regulated VGS signal generated by the voltage control circuit.

5. The apparatus of claim 1, comprising:
a voltage reducer to produce an output signal proportional to a buffered VGS signal and with a scaled amplitude suitable for digital processing within a logic circuit.

6. The apparatus of claim 1, comprising:
a logic circuit to receive a sensed VGS signal of the SiC FET from the sense buffer circuit, the sensed VGS signal within the operational range of the logic circuit.

7. The apparatus of claim 1, comprising:
a driver to provide voltage or current to a gate of the SiC FET suitable to switch the SiC FET between ON and OFF states.

8. The apparatus of claim 7, wherein the driver to provide the voltage or current at least partially based on a sensed VGS signal of the SiC FET provided by the sense buffer circuit.

9. The apparatus of claim 1, wherein the sense buffer circuit further comprises timing control circuitry to synchronize the sampling and buffering of the VGS signal, enabling real-time monitoring of the SiC FET's gate-to-source voltage.

10. The apparatus of claim 1, wherein the sense buffer circuit includes signal conditioning circuitry to modify a VGS signal of the SiC FET.

11. The apparatus of claim 1, wherein the signal conditioning circuitry includes one or more of an analog-to-digital converter, a multiplexer, a comparator, a threshold detector, a signal scaler, or a signal level shifter.

12. The apparatus of claim 1, wherein one or more of the inputs of the sense buffer circuit include high-transconductance low-voltage circuits, configured to accurately track changes in the gate-to-source voltage of the SiC FET.

13. The apparatus of claim 1, wherein the sense buffer circuit includes cascoded low-voltage devices to manage high-voltage swings of the VGS signal while maintaining safe operating conditions for the low-voltage devices.

14. An apparatus, comprising:
a Silicon Carbide (SiC) Field Effect Transistor (FET);
a voltage control circuit to control a gate-to-source voltage (VGS) of the SiC FET;
a sense buffer circuit to sense a VGS signal of the SiC FET, the sense buffer circuit comprising:
one or more low-voltage (LV) devices to produce a buffered version of the VGS signal, the LV devices operating within a smaller input voltage range than the overall sense buffer circuit;
a voltage control circuit to regulate the VGS signal to ensure operation of the LV devices within their input voltage range, wherein the voltage control circuit includes one or more of a voltage scaler, a clamping diode, a voltage attenuator, a floating input, or a signal filter;
isolation circuitry to electrically isolate the high-voltage VGS input signal from the buffered VGS signal, the isolation circuitry including one or more of cascoded transistors, resistive voltage dividers, clamping diodes, or capacitive coupling;
a voltage reducer to receive the buffered VGS signal from the sense buffer circuit and generate a sensed VGS signal with a reduced amplitude;
a logic circuit to receive the sensed VGS signal, wherein the sensed VGS signal is within an operational voltage range compatible with the logic circuit; and
a driver circuit to provide voltage or current to a gate of the SiC FET to switch the SiC FET between ON and OFF states, wherein the driver circuit operates based at least in part on the sensed VGS signal generated by the sense buffer circuit.
